(19) United States
(12) Patent Application Publication
(10) Pub. No.: US 2013/0240020 A1
(43) Pub. Date: Sep. 19, 2013

(54) ULTRAVIOLET LIGHT-ABSORBING SOLAR MODULE AND FABRICATING METHOD THEREOF

(71) Applicants: Wei-Jieh LEE, Hsin-Chu (TW); Chia-Hsun Tsai, Hsin-Chu (TW); Chun-Ming Yang, Hsin-Chu (TW)

(72) Inventors: Wei-Jieh LEE, Hsin-Chu (TW); Chia-Hsun Tsai, Hsin-Chu (TW); Chun-Ming Yang, Hsin-Chu (TW)

(73) Assignee: AU Optronics Corporation, Hsin-Chu (TW)

(21) Appl. No.: 13/596,197

(22) Filed: Aug. 28, 2012

(30) Foreign Application Priority Data
Mar. 16, 2012 (CN) 201210080613.1

(51) Int. Cl. H01L 31/048; H01L 31/18

(52) U.S. Cl. 136/251; 438/67; 257/E31.117

(57) ABSTRACT

An ultraviolet light-absorbing solar module is disclosed. The ultraviolet light transmission of a first sealant disposed between a solar cell and a transparent substrate is greater than the ultraviolet light transmission of a second sealant disposed between the solar cell and a back plate. The ultraviolet light can pass through the first sealant and be utilized by the solar cell. The ultraviolet light can be further absorbed by the second sealant. Therefore the degradation of the back plate caused by being exposed of ultraviolet light can be prevented. A fabricating method of the ultraviolet light-absorbing solar module is also disclosed.

### RELATED APPLICATIONS

This application claims priority to China Application Serial Number 201210080613.1, filed Mar. 16, 2012, which is herein incorporated by reference.

### BACKGROUND

1. Technical Field

The present disclosure relates to a solar module and a fabricating method thereof, and more particularly, to an ultraviolet light-absorbing solar module and a fabricating method thereof.

2. Description of Related Art

Because the oil reserves in the world have been gradually reducing year by year, energy shortage becomes the global focus problem. Concerning the resource depletion, it is imperative to develop and utilize various kinds of alternative energies. With the rise of environmental awareness, solar energy that has advantages of zero pollution and inexhaustibility receives the most attention in the fields of the alternative energies. Accordingly, solar energy panels are increasingly installed in the locations with ample sunshine such as roofs of buildings, squares, etc.

### SUMMARY

The disclosure provides an ultraviolet light-absorbing solar module for improving power generation efficiency and preventing degradation of a back plate caused by being exposed of ultraviolet light.

According to an embodiment of the disclosure, an ultraviolet light-absorbing solar module includes a transparent substrate, a back plate, a plurality of solar cells, a first sealant, and a second sealant. The solar cells are capable of absorbing ultraviolet light, and are disposed between the transparent substrate and the back plate. The light-receiving surfaces of the solar cells face the transparent substrate. The first sealant is located between the transparent substrate and the solar cells. The second sealant is located between the back plate and the solar cells. The first sealant has an ultraviolet light transmission greater than that of the second sealant.

According to another embodiment of the disclosure, a fabricating method of an ultraviolet light-absorbing solar module includes providing a transparent substrate; disposing a first sealant on the transparent substrate; disposing a plurality of solar cells on the first sealant; disposing a second sealant on the solar cells; disposing a back plate on the second sealant; and laminating the transparent substrate, the first sealant, the solar cells, the second sealant, and the back plate. The light-receiving surfaces of the solar cells face the transparent substrate, and the solar cells are capable of absorbing ultraviolet light. The first sealant has an ultraviolet light transmission greater than that of the second sealant.

Because the ultraviolet light transmission of the first sealant between the solar cells and the transparent substrate is greater than the ultraviolet light transmission of the second sealant between the solar cells and the back plate, the ultraviolet light that passes through the first sealant can be absorbed and utilized by the solar cells, and the ultraviolet light that passes through gaps among the solar cells can be absorbed by the second sealant, thereby preventing degradation of the back plate caused by being exposed of ultraviolet light.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial sectional view of a first embodiment of an ultraviolet light-absorbing solar module of the disclosure;

FIG. 2 is a partial sectional view of a second embodiment of the ultraviolet light-absorbing solar module of the disclosure;

FIG. 3 is a partial sectional view of a third embodiment of the ultraviolet light-absorbing solar module of the disclosure;

FIG. 4 is a partial sectional view of a fourth embodiment of the ultraviolet light-absorbing solar module of the disclosure;

FIG. 5 is a partial sectional view of a fifth embodiment of the ultraviolet light-absorbing solar module of the disclosure;

FIG. 6 is a partial sectional view of a sixth embodiment of the ultraviolet light-absorbing solar module of the disclosure;

FIG. 7 is a block diagram of an embodiment of a fabricating method of an ultraviolet light-absorbing solar module of the disclosure; and

FIG. 8 is a block diagram of another embodiment of a fabricating method of an ultraviolet light-absorbing solar module of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In order to improve the power generation efficiency of solar panels, an improved solar module that is capable of absorbing certain part of ultraviolet light is provided. Particularly, the ultraviolet light-absorbing solar module provided by the disclosure can prevent degradation of a back plate in the ultraviolet light-absorbing solar module caused by of the exposure under ultraviolet light.

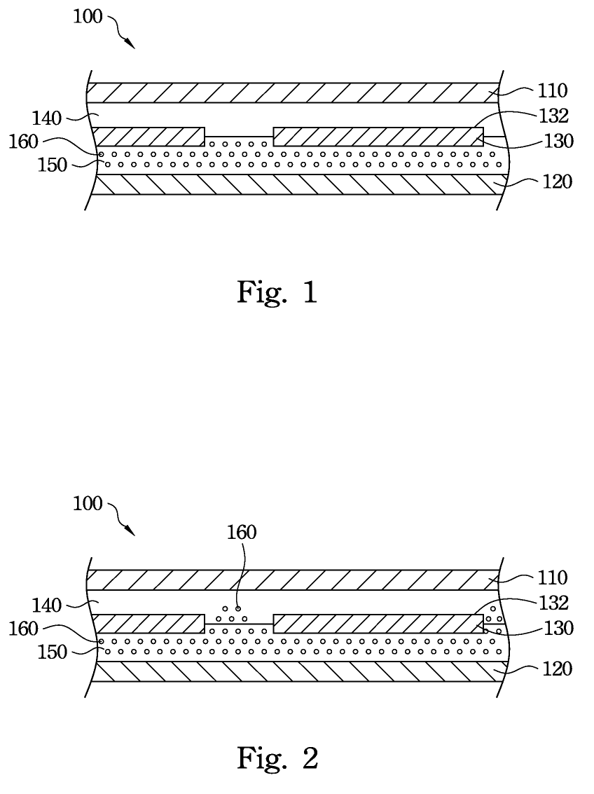

FIG. 1 is a partial sectional view of a first embodiment of an ultraviolet light-absorbing solar module of the disclosure.

The ultraviolet light-absorbing solar module 100 includes a transparent substrate 110, a back plate 120, a plurality of solar cells 130, a first sealant 140, and a second sealant 150. The solar cells 130 are disposed between the transparent substrate 110 and the back plate 120. The light-receiving surfaces 132 of the solar cells 130 (i.e., surfaces of the solar cells 130 used for receiving solar radiation) face the transparent substrate 110. The first sealant 140 is located between the transparent substrate 110 and the solar cells 130. The second sealant 150 is located between the back plate 120 and the solar cells 130. The transparent substrate 110, the solar cells 130, and the back plate 120 can be adhered to each other by the first sealant 140 and the second sealant 150 after heated and laminated. Meanwhile, the solar cells 130 are located between the first sealant 140 and the second sealant 150, and a portion of the first sealant 140 contacts a portion of the second sealant 150.

The solar cells 130 are capable of absorbing ultraviolet light. In order to allow the ultraviolet light to get into the solar cells 130, the first sealant 140 located between the transparent substrate 110 and the solar cells 130 preferably has a high ultraviolet light transmission, so as to allow most of the ultraviolet light to pass through the first sealant 140. In order to protect the back plate 120 from degradation caused by being exposed of the ultraviolet light or prevent the adhesive force between the back plate 120 and the second sealant 150 from decreasing, the second sealant 150 preferably has a low ultraviolet light transmission. In other words, the ultraviolet light transmission of the first sealant 140 is greater than the ultraviolet light transmission of the second sealant 150.

The transparent substrate 110 can be a glass substrate. The back plate 120 can be a plastic substrate. The first sealant 140 and the second sealant 150 include adhesive members that have the same material or different materials. The materials of the adhesive members can include at least one of EVA (ethylene vinyl acetate resin), LDPE (low density polyethylene), HDPE (high density polyethylene), silicone, epoxy, PVB (Polyvinyl Butyral), and TPU (Thermoplastic Polyurethane, TPU), but the disclosure is not limited in this regard. In the embodiment of the disclosure, the first sealant 140 has the adhesive member but does not have any ultraviolet light absorbent. Besides the adhesive member, the second sealant 150 further includes a first ultraviolet light absorbent 160. The second sealant 150 absorbs the ultraviolet light by the first ultraviolet light absorbent 160, so as to reduce the radiation dose of the ultraviolet light transmitted to the back plate 120 and thus reduce the affect of the ultraviolet light applying to the back plate 120.

FIG. 2 is a partial sectional view of a second embodiment of the ultraviolet light-absorbing solar module of the disclosure.

The ultraviolet light-absorbing solar module 100 includes a transparent substrate 110, a back plate 120, a plurality of solar cells 130, a first sealant 140, and a second sealant 150. The solar cells 130 are disposed between the transparent substrate 110 and the back plate 120. The first sealant 140 is located between the transparent substrate 110 and the solar cells 130. The second sealant 150 is located between the back plate 120 and the solar cells 130.

The solar cells 130 are capable of absorbing ultraviolet light. The ultraviolet light transmission of the first sealant 140 is greater than the ultraviolet light transmission of the second sealant 150. In the embodiment of the disclosure, the first sealant 140 and the second sealant 150 can include adhesive members that have the same material or different materials. Both of the first sealant 140 and the second sealant 150 have a first ultraviolet light absorbent 160. The distribution density of the first ultraviolet light absorbent 160 of the first sealant 140 is smaller than the distribution density of the first ultraviolet light absorbent 160 of the second sealant 150, so that most of the ultraviolet light can pass through the first sealant 140 and be absorbed and utilized by the solar cells 130, but is not easy to pass through the second sealant 150 to reach the back plate 120. In a case, the first sealant 140 directly contact the second sealant 150, so the first ultraviolet light absorbent 160 of the first sealant 140 can be formed by a portion of the first ultraviolet light absorbent 160 of the second sealant 150 that is spread to the first sealant 140 during the processes of heating and laminating, but the disclosure is not limited in this regard.

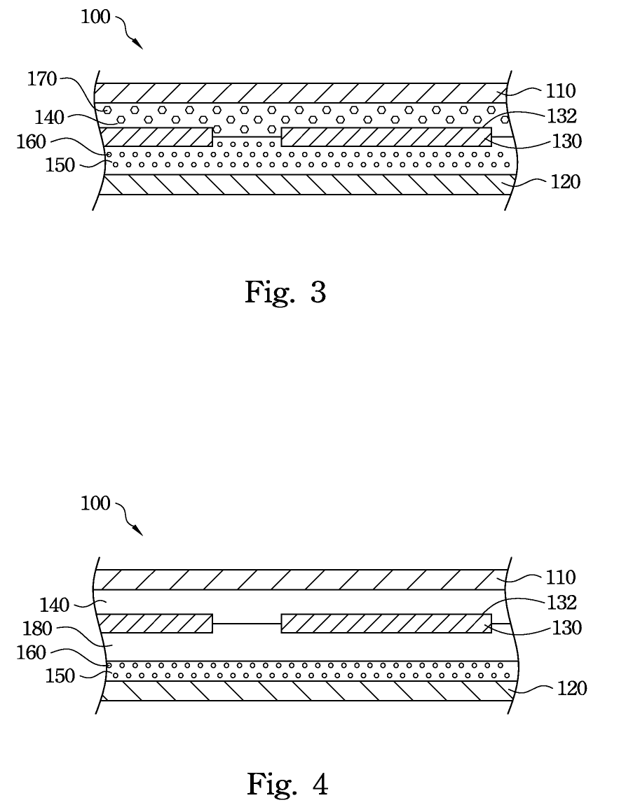

FIG. 3 is a partial sectional view of a third embodiment of the ultraviolet light-absorbing solar module of the disclosure.

The ultraviolet light-absorbing solar module 100 includes a transparent substrate 110, a back plate 120, a plurality of solar cells 130, a first sealant 140, and a second sealant 150. The solar cells 130 are disposed between the transparent substrate 110 and the back plate 120. The first sealant 140 is located between the transparent substrate 110 and the solar cells 130. The second sealant 150 is located between the back plate 120 and the solar cells 130.

The solar cells 130 are capable of absorbing ultraviolet light. The ultraviolet light transmission of the first sealant 140 is greater than the ultraviolet light transmission of the second sealant 150. In the embodiment of the disclosure, the second sealant 150 includes an adhesive member and a first ultraviolet light absorbent 160, and the first sealant 140 includes an adhesive member and a second ultraviolet light absorbent 170. The adhesive member of the first sealant 140 and the adhesive member of the second sealant 150 can include the same material or different materials. The overlapping range between the absorption band of the first ultraviolet light absorbent 160 and the wave band of the ultraviolet light is greater than the overlapping range between the absorption band of the second ultraviolet light absorbent 170 and the wave band of the ultraviolet light. For example, the wave band of the ultraviolet light that can be absorbed and utilized by a solar module is 300-400 nm. The overlapping range between the absorption band of the second ultraviolet light absorbent 170 in the first sealant 140 and the foregoing wave band of the ultraviolet light that can be absorbed and utilized by a solar module is less, so the ultraviolet light with the wave band of 300-400 nm is rarely absorbed by the second ultraviolet light absorbent 170. The ultraviolet light with the wave band of 300-400 nm can pass through the first sealant 140 and be absorbed and utilized by the solar cells 130. The overlapping range between the absorption band of the first ultraviolet light absorbent 160 in the second sealant 150 and the foregoing wave band of the ultraviolet light is more, so the back plate 120 can be prevented from exposing to the ultraviolet light.

FIG. 4 is a partial sectional view of a fourth embodiment of the ultraviolet light-absorbing solar module of the disclosure.

Besides a transparent substrate 110, a back plate 120, a plurality of solar cells 130 capable of absorbing ultraviolet light, a first sealant 140, and a second sealant 150, the ultraviolet light-absorbing solar module 100 further includes a third sealant 180 that is disposed between the solar cells 130 and the second sealant 150. The ultraviolet light transmission of the third sealant 180 is greater than the ultraviolet light transmission of the second sealant 150. The third sealant 180 acts as a buffer layer between the first sealant 140 and the second sealant 150, so as to prevent the first ultraviolet light absorbent 160 in the second sealant 150 from directly spreading to the first sealant 140 and being located at light-receiving surfaces 132 of the solar cells 130 after the processes of heating and laminating. Therefore, the ultraviolet light transmission of the first sealant 140 does not be reduced, and the performances of the solar cells 130 do not be affected.

The solar cells 130 are located between the first sealant 140 and the third sealant 180. A portion of the first sealant 140 contacts a portion of the third sealant 180. The ultraviolet light transmission of the first sealant 140 is greater than the ultraviolet light transmission of the second sealant 150, so the ultraviolet light can get into the solar cells 130 to be absorbed and utilized.

Relationships between the first sealant 140 and the second sealant 150 can be referred to embodiments in FIG. 1 to FIG. 3. In all embodiments introduced below, only changes of the third sealant 180 will be discussed.

In the embodiment of the disclosure, the third sealant 180 has an adhesive member but does not have any ultraviolet light absorbent, and the second sealant 150 includes an adhesive member and the first ultraviolet light absorbent 160. The adhesive member of the third sealant 180 and the adhesive member of the second sealant 150 may have the same material or different materials. The second sealant 150 absorbs the ultraviolet light by the first ultraviolet light absorbent 160, so as to reduce the radiation dose of the ultraviolet light transmitted to the back plate 120 and thus reduce the affect of the ultraviolet light applying to the back plate 120. Furthermore, in a case, the thickness of the third sealant 180 is greater than the second sealant 150, so as to prevent the risk that the first ultraviolet light absorbent 160 gradually spreading to the first sealant 140 after long-term use of the solar module 100.

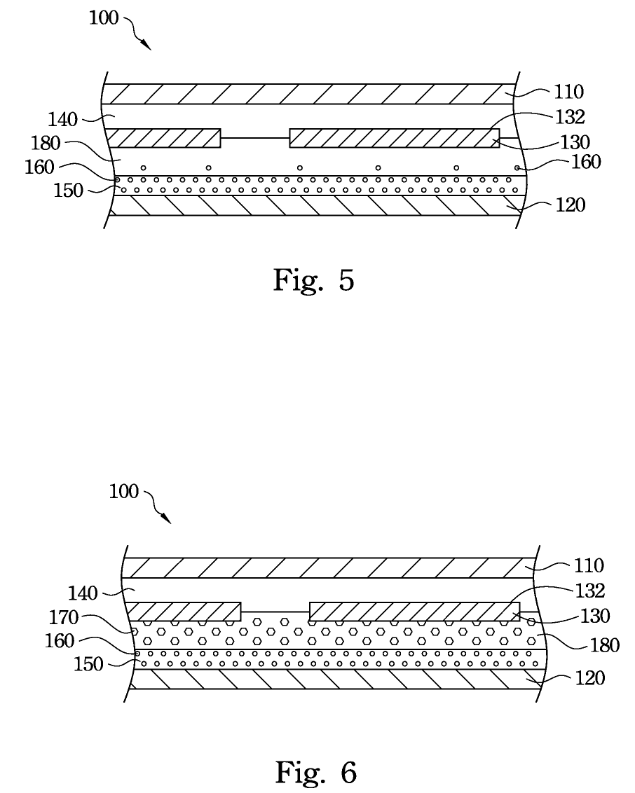

FIG. 5 is a partial sectional view of a fifth embodiment of the ultraviolet light-absorbing solar module of the disclosure.

The ultraviolet light-absorbing solar module 100 includes a transparent substrate 110, a back plate 120, a plurality of solar cells 130 capable of absorbing ultraviolet light, a first sealant 140, a second sealant 150, and a third sealant 180. The ultraviolet light transmission of the third sealant 180 is greater than the ultraviolet light transmission of the second sealant 150. The solar cells 130 are located between the first sealant 140 and the third sealant 180. The third sealant 180 acts as a buffer layer between the first sealant 140 and the second sealant 150. Furthermore, in a case, the thickness of the third sealant 180 is greater than the second sealant 150, so as to prevent the risk that the first ultraviolet light absorbent 160 is gradually spread to the first sealant 140 after long-term use of the solar module 100.

In the embodiment of the disclosure, the third sealant 180 and the second sealant 150 can include adhesive members that have the same material or different materials. Both of the second sealant 150 and the third sealant 180 have a first ultraviolet light absorbent 160. The distribution density of the first ultraviolet light absorbent 160 of the third sealant 180 is smaller than the distribution density of the first ultraviolet light absorbent 160 of the second sealant 150, so that most of the ultraviolet light can pass through the third sealant 180 which acts as a buffer layer, but is not easy to pass through the second sealant 150 to reach the back plate 120. In a case, the third sealant 180 directly contact the second sealant 150, so the first ultraviolet light absorbent 160 of the third sealant 180 can be formed by a portion of the first ultraviolet light absorbent 160 of the second sealant 150 that is spread to the third sealant 180 during the processes of heating and laminating. Because the third sealant 180 acts as a buffer layer, the probability that the first ultraviolet light absorbent 160 is spread to the first sealant 140 is reduced under restrictions of the third sealant 180, so that the utilization efficiency of the ultraviolet light of the solar cells 130 do not be affected.

FIG. 6 is a partial sectional view of a sixth embodiment of the ultraviolet light-absorbing solar module of the disclosure.

The ultraviolet light-absorbing solar module 100 includes a transparent substrate 110, a back plate 120, a plurality of solar cells 130 capable of absorbing ultraviolet light, a first sealant 140, a second sealant 150, and a third sealant 180. The ultraviolet light transmission of the third sealant 180 is greater than the ultraviolet light transmission of the second sealant 150. The solar cells 130 are located between the first sealant 140 and the third sealant 180. The third sealant 180 acts as a buffer layer between the first sealant 140 and the second sealant 150. Furthermore, in a case, the thickness of the third sealant 180 is greater than the second sealant 150, so as to prevent the risk that the first ultraviolet light absorbent 160 is gradually spread to the first sealant 140 after long-term use of the solar module 100.

In the embodiment of the disclosure, the second sealant 150 includes an adhesive member and a first ultraviolet light absorbent 160, and the third sealant 180 includes an adhesive member and a second ultraviolet light absorbent 170. The adhesive member of the third sealant 180 and the adhesive member of the second sealant 150 can have the same material or different materials. The overlapping range between the absorption band of the first ultraviolet light absorbent 160 and the wave band of the ultraviolet light is greater than the overlapping range between the absorption band of the second ultraviolet light absorbent 170 and the wave band of the ultraviolet light. The overlapping range between the absorption band of the first ultraviolet light absorbent 160 in the second sealant 150 and the wave band of the ultraviolet light is more, so the back plate 120 can be prevented from exposing to the ultraviolet light.

Because the third sealant 180 acts as a buffer layer, the probability that to the first ultraviolet light absorbent 160 is spread to the first sealant 140 is reduced under restrictions of the third sealant 180, so that the utilization efficiency of the ultraviolet light of the solar cells 130 do not be affected.

According to practical test results, the power of the third embodiment of the solar module 100 (i.e., the solar module 100 does not have the third sealant 180, and the first sealant 140 and the second sealant 150 have different ultraviolet light absorbents) is 265.989 watt, whereas the power of the sixth embodiment of the solar module 100 (i.e., the solar module 100 further includes third sealant 180) is 266.819 watt. Accordingly, the third sealant 180 that acts as a buffer layer can really reduce the probability that the first ultraviolet light absorbent 160 is spread to the first sealant 140 under restrictions of the third sealant 180.

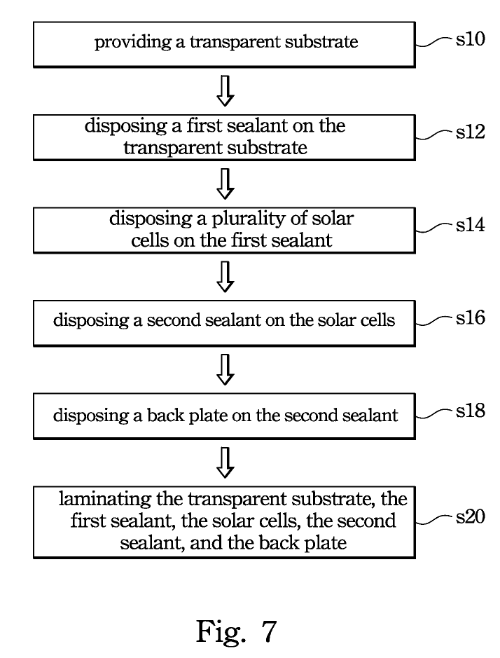

FIG. 7 is a block diagram of an embodiment of a fabricating method of an ultraviolet light-absorbing solar module of the disclosure.

In step s10, a transparent substrate is provided. The transparent substrate can be a glass substrate.

In step s12, a first sealant is disposed on the transparent substrate. The first sealant 140 preferably has a high ultraviolet light transmission, so as to allow most of the ultraviolet light to pass through the first sealant 140. The first sealant 140 includes an adhesive member, and materials of the adhesive member can include at least one of EVA (ethylene vinyl acetate resin), LDPE (low density polyethylene), HDPE (high density polyethylene), silicone, epoxy, PVB (Polyvinyl Butyral), and TPU (Thermoplastic Polyurethane, TPU), but the disclosure is not limited in this regard.

In step s14, a plurality of solar cells are disposed on the first sealant. The solar cells are capable of absorbing ultraviolet light, and light-receiving surfaces of the solar cells face the transparent substrate.

In step s16, a second sealant is disposed on the solar cells. The solar cells are located between the first sealant and the second sealant. The light-receiving surfaces of the solar cells directly contact the first sealant, and other surfaces opposite to the light-receiving surface of the solar cells directly contact the second sealant.

The second sealant 16 includes an adhesive member, and materials of the adhesive member can include at least one of EVA (ethylene vinyl acetate resin), LDPE (low density polyethylene), HDPE (high density polyethylene), silicone, epoxy, PVB (Polyvinyl Butyral), and TPU (Thermoplastic Polyurethane, TPU), but the disclosure is not limited in this regard. The second sealant can further include a first ultraviolet light absorbent.

The ultraviolet light transmission of the first sealant is greater than the ultraviolet light transmission of the second sealant, so that the solar cells can absorb and utilize the ultraviolet light. The first sealant can have an adhesive member but does not have any ultraviolet light absorbent. Alternatively, the first sealant can include a first ultraviolet absorbent, and the distribution density of the first ultraviolet light absorbent of the first sealant is smaller than the distribution density of the first ultraviolet light absorbent of the second sealant. Alternatively, the first sealant can include a second ultraviolet absorbent, and the overlapping range between the absorption band of the first ultraviolet light absorbent of the second sealant and the wave band of the ultraviolet light is greater than the overlapping range between the absorption band of the second ultraviolet light absorbent of the first sealant and the wave band of the ultraviolet light.

In step s18, a back plate is disposed on the second sealant. The back plate can be a plastic substrate. The second sealant can absorb most of the ultraviolet light and thus reduce the radiation dose of the ultraviolet light transmitted to the back plate, so as to prevent the back plate from degradation caused by being exposed of the ultraviolet light or prevent the adhesive force between the back plate and the second sealant from decreasing.

Finally, in step s20, the transparent substrate, the first sealant, the solar cells, the second sealant, and the back plate are laminated. In step s20, the transparent substrate is further heated. That is, the transparent substrate is the component that is directly heated in step s20. In a case, the heating temperature is about 140-160 degrees Celsius. Because the solar cells are arranged separately, a portion of the first sealant directly contacts a portion of the second sealant after laminating.

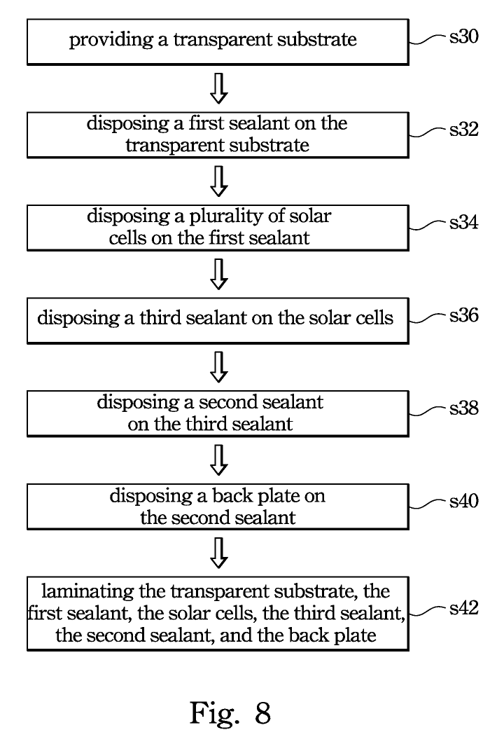

FIG. 8 is a block diagram of another embodiment of a fabricating method of an ultraviolet light-absorbing solar module of the disclosure.

In step s30, a transparent substrate is provided. The transparent substrate can be a glass substrate.

In step s32, a first sealant is disposed on the transparent substrate. The first sealant 140 preferably has a high ultraviolet light transmission, so as to allow most of the ultraviolet light to pass through the first sealant 140. The first sealant 140 includes an adhesive member, and materials of the adhesive member can include at least one of EVA (ethylene vinyl acetate resin), LDPE (low density polyethylene), HDPE (high density polyethylene), silicone, epoxy, PVB (Polyvinyl Butyral), and TPU (Thermoplastic Polyurethane, TPU), but the disclosure is not limited in this regard.

In step s34, a plurality of solar cells are disposed on the first sealant. The solar cells are capable of absorbing ultraviolet light, and light-receiving surfaces of the solar cells face the transparent substrate.

In step s36, a third sealant is disposed on the solar cells. The solar cells are located between the first sealant and the third sealant. The light-receiving surfaces of the solar cells directly contact the first sealant, and other surfaces opposite to the light-receiving surface of the solar cells directly contact the third sealant.

The third sealant includes an adhesive member, and materials of the adhesive member can include at least one of EVA (ethylene vinyl acetate resin), LDPE (low density polyethylene), HDPE (high density polyethylene), silicone, epoxy, PVB (Polyvinyl Butyral), and TPU (Thermoplastic Polyurethane, TPU), but the disclosure is not limited in this regard.

In step s38, a second sealant is disposed on the third sealant. The third sealant acts as a buffer layer between the first sealant and the second sealant. The second sealant include an adhesive member, and materials of the adhesive member can include at least one of EVA (ethylene vinyl acetate resin), LDPE (low density polyethylene), HDPE (high density polyethylene), silicone, epoxy, PVB (Polyvinyl Butyral), and TPU (Thermoplastic Polyurethane, TPU), but the disclosure is not limited in this regard. The second sealant can further include a first ultraviolet light absorbent.

The ultraviolet light transmission of the first sealant is greater than the ultraviolet light transmission of the second sealant, so that the solar cells can absorb and utilize the ultraviolet light. The ultraviolet light transmission of the third sealant that acts as a buffer layer is greater than the ultraviolet light transmission of the second sealant, so that most of the ultraviolet light is absorbed by the second sealant.

The first sealant or the third sealant can have an adhesive member but does not have any ultraviolet light absorbent. Alternatively, the first sealant or the third sealant can include a first ultraviolet absorbent, and the distribution density of the first ultraviolet light absorbent of the first sealant or the third sealant is smaller than the distribution density of the first ultraviolet light absorbent of the second sealant. Alternatively, the first sealant or the third sealant can include a second ultraviolet absorbent, and the overlapping range between the absorption band of the first ultraviolet light absorbent of the second sealant and the wave band of the ultraviolet light is greater than the overlapping range between the absorption band of the second ultraviolet light absorbent of the first sealant or the third sealant and the wave band of the ultraviolet light.

In step s40, a back plate is disposed on the second sealant. The back plate can be a plastic substrate. The second sealant can absorb most of the ultraviolet light and thus reduce the radiation dose of the ultraviolet light transmitted to the back plate, so as to prevent the back plate from degradation caused by being exposed of the ultraviolet light or prevent the adhesive force between the back plate and the second sealant from decreasing.

Finally, in step s42, the transparent substrate, the first sealant, the solar cells, the third sealant, the second sealant, and the back plate are laminated. In step s42, the transparent substrate is further heated. That is, the transparent substrate is the component that is directly heated in step s42. In a case, the heating temperature is about 140-160 degrees Celsius. Because the solar cells are arranged separately, a portion of the first sealant directly contacts a portion of the third sealant after laminating. Accordingly, the third sealant 180 that acts as a buffer layer can really reduce the probability that the first ultraviolet light absorbent 160 is spread to the first sealant 140 under restrictions of the third sealant 180, so that the utilization efficiency of the ultraviolet light of the solar cells 130 do not be affected.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An ultraviolet light-absorbing solar module comprising:
a transparent substrate;
a back plate;
a plurality of solar cells capable of absorbing ultraviolet light and disposed between the transparent substrate and the back plate, wherein light-receiving surfaces of the solar cells face the transparent substrate;
a first sealant located between the transparent substrate and the solar cells; and
to a second sealant located between the back plate and the solar cells, wherein an ultraviolet light transmission of the first sealant is greater than that of the second sealant.

2. The ultraviolet light-absorbing solar module of claim 1, wherein the transparent substrate is a glass substrate.

3. The ultraviolet light-absorbing solar module of claim 1, wherein each of the first sealant and the second sealant comprise an adhesive member, and the second sealant comprises a first ultraviolet light absorbent.

4. The ultraviolet light-absorbing solar module of claim 3, wherein the first sealant further comprises the first ultraviolet light absorbent, and a distribution density of the first ultraviolet light absorbent of the first sealant is smaller than that of the first ultraviolet light absorbent of the second sealant.

5. The ultraviolet light-absorbing solar module of claim 3, wherein the first sealant further comprises a second ultraviolet light absorbent, and an overlapping range between the absorption band of the first ultraviolet light absorbent and the wave band of ultraviolet light is greater than that between the absorption band of the second ultraviolet light absorbent and the wave band of the ultraviolet light.

6. The ultraviolet light-absorbing solar module of claim 1, wherein a portion of the first sealant contacts a portion of the second sealant, and the to solar cells are located between the first sealant and the second sealant.

7. The ultraviolet light-absorbing solar module of claim 1, further comprising a third sealant disposed between the solar cells and the second sealant, wherein an ultraviolet light transmission of the third sealant is greater than the ultraviolet light transmission of the second sealant.

8. The ultraviolet light-absorbing solar module of claim 7, wherein each of the third sealant and the second sealant comprise an adhesive member, and the second sealant comprises a first ultraviolet light absorbent.

9. The ultraviolet light-absorbing solar module of claim 8, wherein the third sealant further comprises the first ultraviolet light absorbent, and a distribution density of the first ultraviolet light absorbent of the third sealant is smaller than that of the first ultraviolet light absorbent of the second sealant.

10. The ultraviolet light-absorbing solar module of claim 8, wherein the third sealant further comprises a second ultraviolet light absorbent, and an overlapping range between the absorption band of the first ultraviolet light absorbent and the wave band of ultraviolet light is greater than that between the absorption band of the second ultraviolet light absorbent and the wave band of the ultraviolet light.

11. The ultraviolet light-absorbing solar module of claim 7, wherein a portion of the first sealant contacts a portion of the third sealant, and the solar cells are located between the first sealant and the third sealant.

12. A fabricating method of an ultraviolet light-absorbing solar module, comprising the steps of:
providing a transparent substrate;
disposing a first sealant on the transparent substrate;
disposing a plurality of solar cells on the first sealant, wherein light-receiving surfaces of the solar cells face the transparent substrate, and the solar cells are capable of absorbing ultraviolet light;
disposing a second sealant on the solar cells, wherein an ultraviolet light transmission of the first sealant is greater than that of the second sealant;
disposing a back plate on the second sealant; and
laminating the transparent substrate, the first sealant, the solar cells, the second sealant, and the back plate.

13. The fabricating method of claim 12, wherein the step of laminating the transparent substrate, the first sealant, the solar cells, the second sealant, and the back plate further comprises heating the transparent substrate.

14. The fabricating method of claim 12, wherein each of the first sealant and the second sealant comprise an adhesive member, and the second sealant comprises a first ultraviolet light absorbent.

15. The fabricating method of claim 14, wherein the first sealant further comprises the first ultraviolet light absorbent, and a distribution density of the first ultraviolet light absorbent of the first sealant is smaller than that of the first ultraviolet light absorbent of the second sealant.

16. The fabricating method of claim 14, wherein the first sealant further comprises a second ultraviolet light absorbent, and an overlapping range between the absorption band of the first ultraviolet light absorbent and the wave band of ultraviolet light is greater than that between the absorption band of the second ultraviolet light absorbent and the wave band of the ultraviolet light.

17. The fabricating method of claim 12, a portion of the first sealant contacts a portion of the second sealant, and the solar cells are located between the first sealant and the second sealant.

18. The fabricating method of claim 12, further comprising disposing a third sealant on the solar cells, so as to make the third sealant be located between the solar cells and the second sealant, wherein an ultraviolet light transmission of the third sealant is greater than the ultraviolet light transmission of the second sealant.

19. The fabricating method of claim 18, wherein each of the third sealant and the second sealant comprise an adhesive member, and the second sealant comprises a first ultraviolet light absorbent.

20. The fabricating method of claim 19, wherein the third sealant further comprises the first ultraviolet light absorbent, and a distribution density of the first ultraviolet light absorbent of the third sealant is smaller than that of the first ultraviolet light absorbent of the second sealant.

21. The fabricating method of claim 19, wherein the third sealant further comprises a second ultraviolet light absorbent, and an overlapping range between the absorption band of the first ultraviolet light absorbent and the wave band of ultraviolet light is greater than that between the absorption band of the second ultraviolet light absorbent and the wave band of the ultraviolet light.

22. The fabricating method of claim 18, wherein a portion of the first sealant contacts a portion of the third sealant, and the solar cells are located between the first sealant and the third sealant.
